(19) United States
(12) Patent Application Publication
(10) Pub. No.: US 2010/0188820 A1
(43) Pub. Date: Jul. 29, 2010

(54) METHOD FOR ASSEMBLING MEMORY MODULE WITH HEAT DISSIPATING SHEET AND APPARATUS THEREOF

(76) Inventors: Wei-Hau CHEN, Taishan Shiang (TW); Shih-Hsi Yen, Taishan Shiang (TW)

Correspondence Address: HDLS Patent & Trademark Services, P.O. BOX 220746, CHANTILLY, VA, 20153-0746, US

(21) Appl. No.: 12/360,186

(22) Filed: Jan. 27, 2009

(51) Int. Cl. H05K 7/20; B21D 39/00

(52) U.S. Cl. 361/719; 29/428

(57) ABSTRACT

A method for assembling memory module with heat dissipating sheet includes the flowing steps: providing a heat dissipating sheet; providing a memory module having a circuit board and at least one chip arranged on the circuit board; arranging the circuit board perpendicularly on the heat dissipating sheet; and folding at least a part of the heat dissipating sheet toward the chip and adhering the part of the heat dissipating sheet to the chip by the glue. Besides, an apparatus which the method of the present invention could perform on is also provided.

### BACKGROUND OF THE INVENTION

1. Field of the Invention

The present invention relates to an assembling method and apparatus thereof, in particular to a method for assembling a memory module with a heat dissipating sheet and apparatus thereof.

2. Description of Related Art

As the rapid development of computer technology, it needs to appropriately remove the heat generated not only from the central processing unit (CPU) of the computer, but also from the VGA card and the memory module, to prevent damage caused by overheating. FIG. 1 shows a conventional heat dissipating clamp. The clamp 1a is used to assemble a memory module 2a and to cover a chip 20a of the memory module 2a. The heat dissipating clamp 1a is of an inverted U-shaped cross section and has a top portion and two elastic side portions respectively downwardly extended from the top portion. The memory module 2a and the chip 20a are clamped between the two elastic side portions, thus heat generated from the chip 20a can dissipate into the heat dissipating clamp 1a.

However, the heat dissipating clamp 1a is manufactured in advanced and then is assembled to the memory module 2a by apparatus. In other word, the aforementioned two-steps assembling method seems to be complicated and needs to be simplified.

### SUMMARY OF THE INVENTION

One object of the present invention is to provide a method for assembling memory module with heat dissipating sheet which is simplified and is capable of increasing the efficiency of assembling.

Another object of the present invention is to provide an apparatus on which the abovementioned method of the present invention could perform. In order to achieve aforementioned object, the method for assembling memory module with heat dissipating sheet includes the flowing steps: providing a heat dissipating sheet; providing a memory module having a circuit board and at least one chip arranged on the circuit board; arranging the circuit board perpendicularly on the heat dissipating sheet; and folding at least a part of the heat dissipating sheet toward the chip and adhering the part of the heat dissipating sheet to the chip by the glue.

In order to achieve aforementioned object, the apparatus for assembling memory module with heat dissipating sheet mainly includes a platform, two posts and two plates. The two posts are arranged on the platform. Each of the post includes a vertically extended groove facing the other post. The grooves are used for holding and positioning a memory module with a chip thereon between the posts. The two plates are pivotably connected between the posts and below the memory module. The plates each have a top surface and the two top surfaces are coplanar with each other and on which a heat dissipating sheet is laid. At least one plate is configured to be able to rotate upwardly to fold at least a part of the heat dissipating sheet toward the chip on the memory module.

### BRIEF DESCRIPTION OF THE DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a cross section view of a conventional assembly of memory module and heat dissipating clamp;

FIG. 2 is flow chart of the method for assembling memory module and heat dissipating sheet of the present invention;

FIG. 3 to 7 are perspective views illustrating various steps of the method for assembling memory module and heat dissipating sheet of the present invention;

FIG. 8 is a cross section view of the assembly of memory module and heat dissipating sheet of the present invention;

FIG. 9 is a cross section view of the apparatus of the present invention; and

FIG. 10 is another cross section view of the apparatus of the present invention.

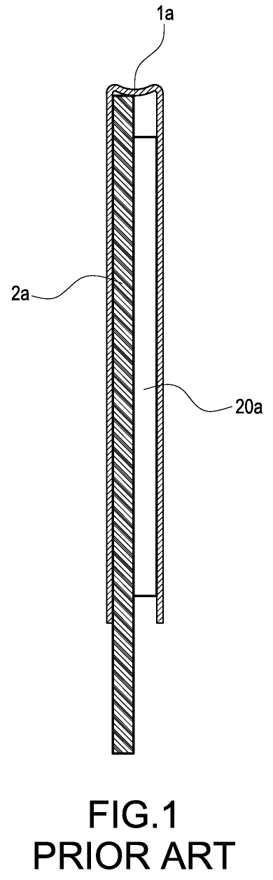

### DETAILED DESCRIPTION OF THE INVENTION

A detailed description of the present invention will be made with reference to the accompanying drawings.

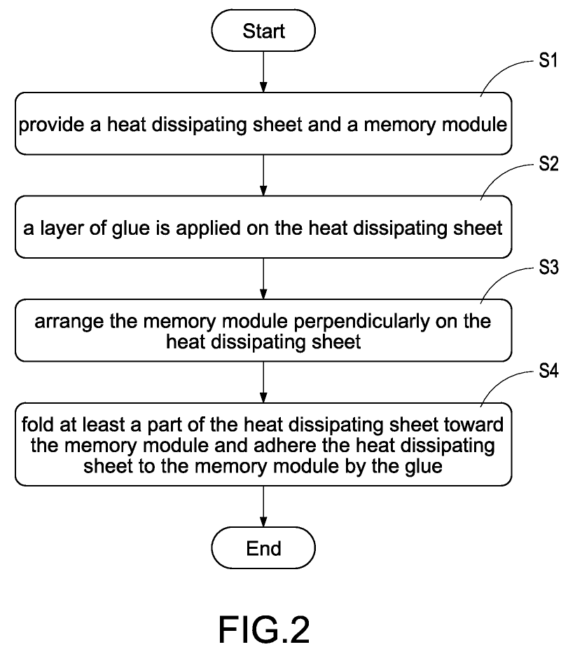

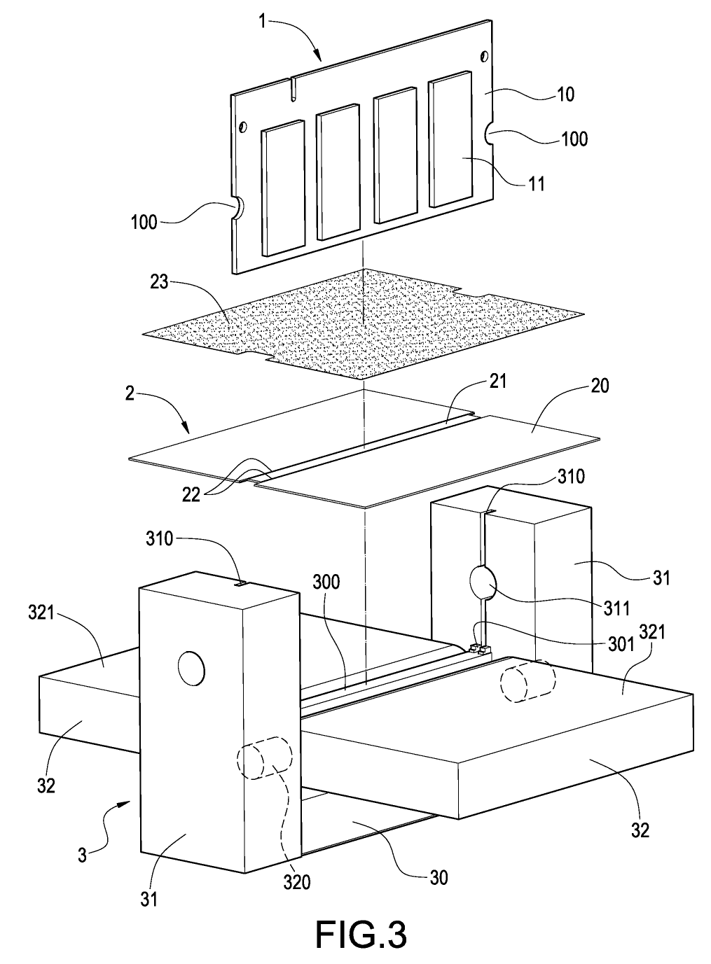

FIG. 2 shows a flow chart of steps of the method for assembling a memory module with a heat dissipating sheet according an embodiment of the present invention. As FIG. 3 shows, an apparatus 3 for assembling the memory module 1 with the heat dissipating sheet 2 according to an embodiment of the present invention mainly includes a platform 30, two posts 31 and two plates 32. The memory module 1 may be a random access memory (RAM) module and has a circuit board 10 and at least one chip 11 arranged on the circuit board 10. Two indents 100 are respectively formed on two sides of the circuit board 10. The heat dissipating sheet 2 includes two side portions 20 and a neck portion 21 connected with the two side portions 20. Two indent lines 22 are formed between the two side portions 20 and the neck portion 21.

The platform 30 is used to mount the posts 31 and the plates 32. The posts 31 are spacely arranged in the platform 30. Each of the post 31 includes a vertically extended groove 310 facing the other post 31. The grooves 310 are used for holding and positioning the circuit board 10 of the memory module 1 between the posts 31. The plates 32 are arranged below the memory module 1 and are pivotably connected between the posts 31. Each of the plates 32 has a top surface 321. The two top surfaces 321 of the plates 32 are coplanar with each other and on which the heat dissipating sheet 2 is laid. The plates 32 are able to rotate upwardly to fold at least a part of the heat dissipating sheet 2 toward the chip 11 on the memory module 1.

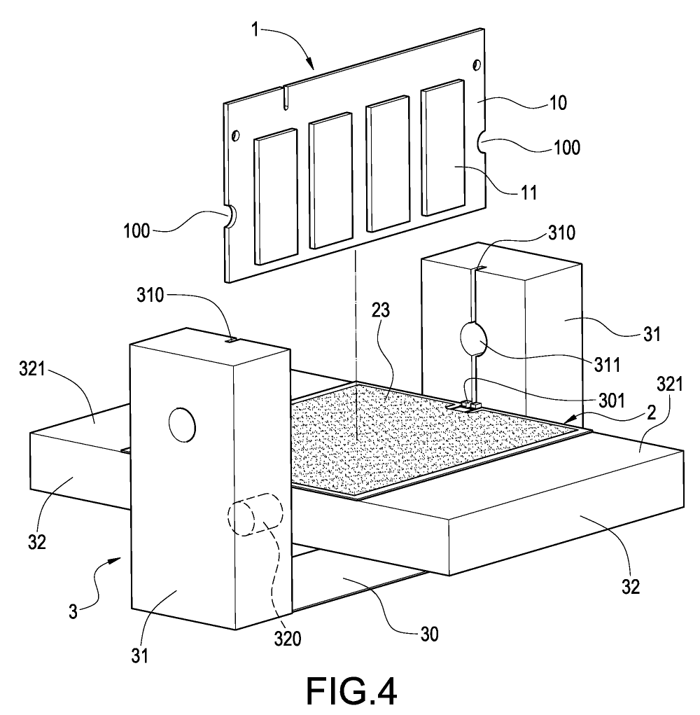

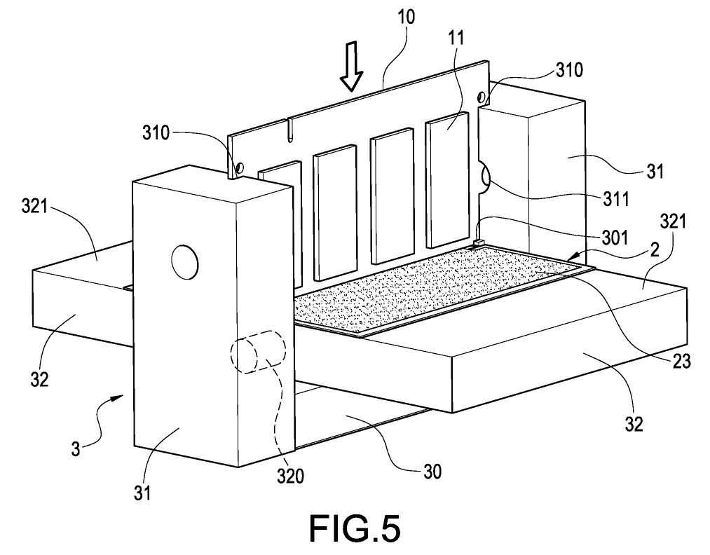

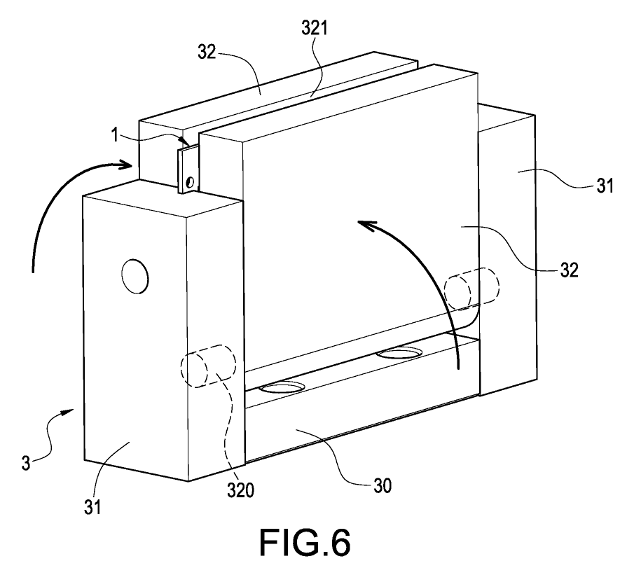

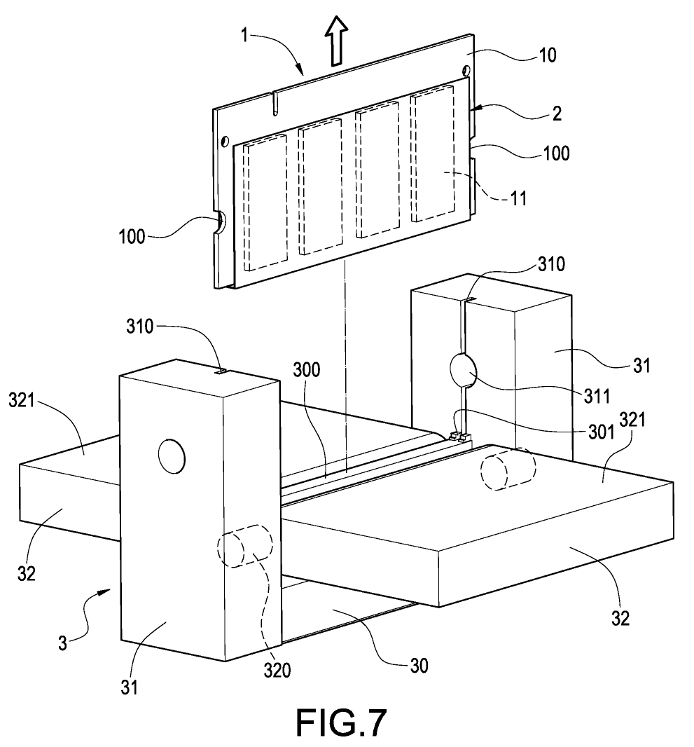

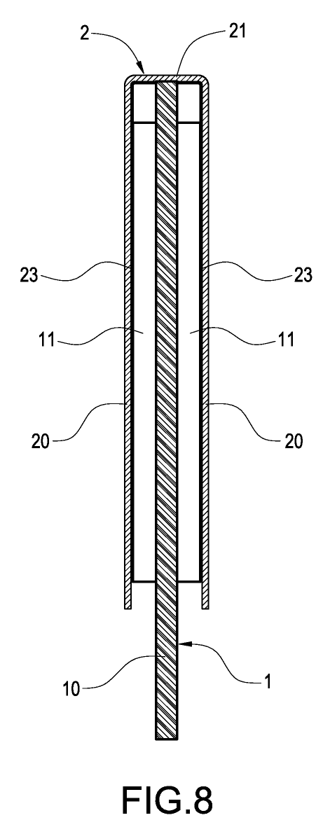

The method for assembling the memory module 1 with the heat dissipating sheet 2 which performs on the apparatus 3 is described below. As FIG. 3 shows, in step S1, the heat dissipating sheet 2 and the memory module 1 are provided. Then, as FIG. 4 shows, in step S2, a layer of glue 23 is applied on at least two side portions 20 of the heat dissipating sheet 2 which is to be laid on the two plates 32 of the apparatus 3. The surface of the heat dissipating sheet 2 with the layer of glue 23 thereon is facing upwardly. The glue 23 is heat conductive glue. Next, as FIG. 5 shows, in step S3, the circuit board 10 of the memory module 1 is inserted into the grooves 310 and is perpendicularly on the heat dissipating sheet 2. Finally, as FIG. 6 shows, in step S4, the side portions 20 of the heat dissipating sheet 2 are folded along the indent line 22 and toward the chip 11 on the circuit board 10 by rotating the plates 32 upwardly. The side portions 20 of the heat dissipating sheet 2 are adhered to the chip 11 by the glue. After that, as FIG. 7 shows, the assembly of the memory module 1 and the heat dissipating sheet 2 is ready to take out from the grooves 310 of the apparatus 3 and is completed as FIG. 8 shows.

Besides, as FIG. 3 shows, a dike 300 can be further arranged on the platform 30 and located between the plates 32. The dike 300 has a top surface coplanar with the top surfaces of the plates 32. Two notches 301 which respectively align with the grooves 310 are formed on the dike 300 for positioning the memory module 1.

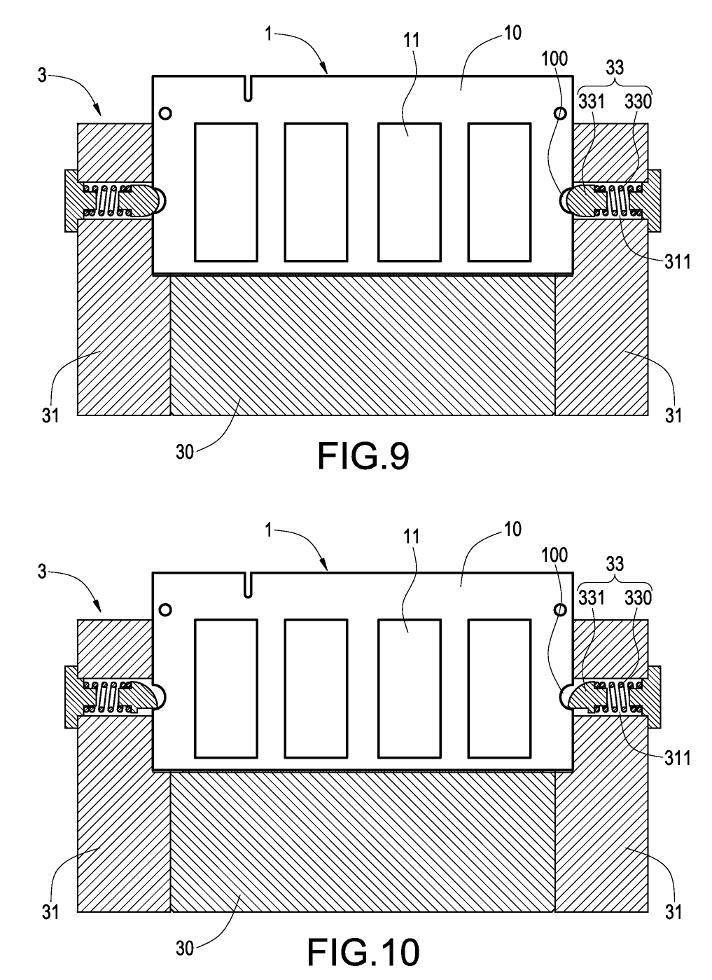

Further, as FIG. 3 and FIG. 9 show, two through holes 311 are respectively formed on the posts 31 and connected with the grooves 310. The apparatus 3 further includes two elastic positioning devices 33 respectively arranged in the through holes 311 for positioning the memory module 1. The elastic positioning devices 33 each has an elastic member 330 and a positioning member 331 connected to the elastic member 330. The positioning members 331 are used for bearing against the memory module 1 by the elastic member 330. In this embodiment, the elastic member 330 is a compression spring. The positioning member 331 may have a semi-spherical head for bearing against the memory module 1. In practical use, the positioning member 331 may also have a quarter-spherical head for bearing against the memory module 1.

Besides, a plurality of the apparatuses 3 of the present invention can be assembled together, and the correspondingly axles 320 of the plates 32 of the apparatuses 3 are connected. Such that the correspondingly plates 32 can rotate at the same time to increase the efficiency of assembling in mass production.

Although the present invention has been described with reference to the foregoing preferred embodiments, it will be understood that the invention is not limited to the details thereof. Various equivalent variations and modifications can still occur to those skilled in this art in view of the teachings of the present invention. Thus, all such variations and equivalent modifications are also embraced within the scope of the invention as defined in the appended claims.

What is claimed is:

1. A method for assembling memory module with heat dissipating sheet, comprising:
(a) providing a heat dissipating sheet;
(b) providing a memory module having a circuit board and at least one chip arranged on the circuit board;
(c) arranging the circuit board perpendicularly on the heat dissipating sheet; and
(d) folding at least a part of the heat dissipating sheet toward the chip and adhering the part of the heat dissipating sheet to the chip by the glue.

2. The method according to claim 1, wherein the part of the heat dissipating sheet is adhered to the chip by glue.

3. The method according to claim 2, wherein the glue is heat conductive glue.

4. An apparatus for assembling memory module with heat dissipating sheet, comprising:
a platform;
two posts arranged on the platform, each of the post comprising a vertically extended groove facing the other post, the grooves being for holding and positioning a memory module with a chip thereon between the posts; and
two plates pivotably connected between the posts and below the memory module, the plates each having a top surface, the two top surfaces being coplanar with each other and on which a heat dissipating sheet is laid,
wherein at least one plate is configured to be able to rotate upwardly to fold at least a part of the heat dissipating sheet toward the chip on the memory module.

5. The apparatus according to claim 4, wherein a dike is arranged on the platform and located between the plates and the dike has a top surface coplanar with the top surfaces of the plates and two notches which respectively align with the grooves are formed on the dike for positioning the memory module.

6. The apparatus according to claim 4, wherein two through holes are respectively formed on the posts and connected with the grooves, the apparatus further comprising two elastic positioning devices respectively arranged in through holes for positioning the memory module.

7. The apparatus according to claim 6, wherein the elastic positioning devices each has an elastic member and a positioning member connected to the elastic member and bearing against the memory module by the elastic member.

8. The apparatus according to claim 7, wherein the elastic member is a compression spring.

9. The apparatus according to claim 7, wherein the positioning member has a semi-spherical head which bears against the memory module.

10. The apparatus according to claim 7, wherein the positioning member has a quarter-spherical head which bears against the memory module.
